(19) United States
(12) Patent Application Publication
(10) Pub. No.: US 2011/0265875 A1
(43) Pub. Date: Nov. 3, 2011

(54) COPPER AND INDIUM BASED PHOTOVOLTAIC DEVICES AND ASSOCIATED METHODS

(75) Inventor: Martin U. Pralle, Wayland, MA (US)

(73) Assignee: SiOnyx, Inc., Beverly, MA (US)

(21) Appl. No.: 13/099,933

(22) Filed: May 3, 2011

Related U.S. Application Data
(60) Provisional application No. 61/330,684, filed on May 3, 2010.

(51) Int. Cl. H01L 31/0296; H01L 31/0236; H01L 31/18; H01L 31/0264; H01L 31/032

(52) U.S. Cl. 136/260; 136/262; 136/265; 438/71; 257/E31.13

(57) ABSTRACT

Optoelectronic devices having enhanced conversion efficiencies and associated methods are provided. In one aspect, for example, a method of making an optoelectronic device can include applying an absorption layer onto a support substrate, the absorption layer including a material such as CIGS, CIG, CI, CZT, CdTe, and combinations thereof. Additional steps include providing a element-rich environment in proximity to the absorption layer, and irradiating at least a portion of the absorption layer with laser radiation through the element-rich environment thereby incorporating the element into the absorption layer.

### PRIORITY DATA

This application claims the benefit of U.S. Provisional Patent Application Ser. No. 61/330,684, filed on May 3, 2010, which is incorporated herein by reference.

### BACKGROUND

The interaction of light with semiconductor materials is at the core of many important innovations. With the rising cost of fossil fuels, alternative energy solutions for power have become increasingly important. One common approach is using photovoltaic devices such as solar cells to absorb and convert light rays from the sun into usable energy. Photovoltaics have been used for years with increasing developments and improvements to the technology. A typical photovoltaic device, for example, can include a photovoltaic cell formed from a silicon material. Silicon is known to absorb a majority of incident visible light having wavelengths in the range of about 300 nm to 900 nm. This, combined with quantum efficiency in the visible spectrum, make silicon a good choice for light absorption. However, because of the optical band gap of silicon (i.e. 1.12 eV or alternatively 1107 nm), many wavelengths of light are transparent to silicon passing through the material, and are thus not absorbed.

CuInSe₂ (CIS) is a useful semiconductor material for photovoltaic energy conversion. As photovoltaic technology has evolved, gallium (Ga) has been introduced into the CIS crystal to shift the bandgap from 1.2 eV to 1.3 eV. This shift enabled the CIGS semiconductor device to target the peak efficiency bandgap for a single junction photovoltaic device.

### SUMMARY

The present disclosure provides optoelectronic devices having enhanced conversion efficiencies and associated methods. In one aspect, for example, a method of making an optoelectronic device can include applying an absorption layer onto a support substrate, the absorption layer including a material such as CIGS, CIG, CI, CZT, and combinations thereof. Additional steps include providing a dopant-rich environment in proximity to the absorption layer, and irradiating at least a portion of the absorption layer with laser radiation through the dopant-rich environment thereby incorporating the dopant into the absorption layer. In another aspect, the method further includes annealing the absorption layer to a temperature of from about 200° C. to about 600° C. In yet another aspect, the method can further include forming a textured region at the absorption layer. In some aspects, the formation of the textured region and the doping of the absorption layer are performed substantially simultaneously with a pulsed laser.

An optoelectronic device can include an absorption layer disposed on a support substrate, where the absorption layer includes a material such as CIGS, CIG, CI, CZT, and combinations thereof. The absorption layer is additionally doped with a dopant. In one aspect, the conversion efficiency of the device is at least about 15%. In another aspect, the conversion efficiency of the device is at least about 20%. In yet another aspect, the conversion efficiency of the device is at least about 25%.

### BRIEF DESCRIPTION OF THE DRAWINGS

For a further understanding of the nature and advantages of the present disclosure, reference is being made to the following detailed description of embodiments and in connection with the accompanying drawings, in which:

FIG. 1 is a cross-sectional view of a semiconductor device in accordance with an embodiment of the present disclosure;

FIG. 2 is a cross-sectional view of a semiconductor structure in accordance with another embodiment of the present disclosure; and

FIG. 3 is a flow chart depiction of a method of making a semiconductor device in accordance with yet another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the term “open circuit voltage” refers to the maximum voltage across the device. In other words, it is the maximum voltage across the device when in sunlight with no external load applied.

As used herein, the terms “disordered surface” and “textured surface” can be used interchangeably, and refer to a surface having a topology with nano- to micron-sized surface variations. Although any texturing technique is considered to be within the present scope, in one aspect the texturing is formed by the irradiation of laser pulses. Furthermore, while the characteristics of a textured surface can be variable depending on the materials and techniques employed, in one aspect such a surface can be several hundred nanometers thick and made up of nanocrystallites (e.g. from about 10 to about 50 nanometers), nanopores, and the like. In another aspect, such a surface can include micron-sized structures (e.g. about 2 μm to about 60 μm). In yet another aspect, the surface can include nano-sized and/or micron-sized structures from about 5 nm and about 500 μm.

As used herein, the terms “surface modifying,” “surface modification,” and “texturing” can be used interchangeably, and refer to the altering of a surface of a semiconductor material using a texturing technique. In one specific aspect, surface modification can be carried out by processes using primarily laser radiation or laser radiation in combination with a dopant or an elemental source, whereby the laser radiation facilitates the incorporation of the dopant or the element into a surface of the semiconductor material. Accordingly, in one aspect surface modification includes doping the material or alloying an element with the material.

As used herein, the term “fluence” refers to the amount of energy from a single pulse of laser radiation that passes through a unit area. In other words, “fluence” can be described as the energy density of one laser pulse.

As used herein, the term “target region” refers to an area of a semiconductor material that is intended to be surface modified using laser radiation. The target region of a semiconductor material can vary as the surface modifying process progresses. For example, after a first target region is surface modified, a second target region may be selected on the same semiconductor material.

As used herein, the term “absorptance” refers to the fraction of incident electromagnetic radiation absorbed by a material or device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

In various aspects of the present disclosure, photovoltaic devices and methods of making photovoltaic devices having enhanced responsivity and enhanced conversion efficiency are provided. Photovoltaic solar cells, for example, can be made from various silicon materials. For example, amorphous silicon has a conversion efficiency in the range of about 2% to about 9% when used in such solar cells. Crystalline silicon, in either multicrystal or monocrystal forms, can also be used, having conversion efficiencies in the range of from about 14% (multicrystal) to about 20% (monocrystal).

Cu—In—Ga—Se (CIGS) solar cells, on the other hand, can have conversion efficiencies of up to about 19%. Conversion efficiency as used herein refers to energy conversion efficiency (i.e. the ability to convert energy from incident electromagnetic radiation to usable energy). In addition to higher efficiency, CIGS solar cells do not degrade over long-term exposure to sunlight, which enables use in high radiation environments. CIGS materials can be developed and manufactured at a lower cost compared to crystalline silicon, and can be formed on flexible substrates enabling use in a broad range of applications.

The addition of Ga to Cu—In—Se (CIS) materials shifts the bandgap from 1.2 eV to 1.3 eV. This shift enables the semiconductor to target peak wavelengths at reasonable efficiencies for a single junction photovoltaic device. Additionally, the bandgap can be further shifted to at least 1.4 eV by introducing sulfur as a substitutional alloy on the Se lattice position. This shift in energy gap enables the theoretical peak conversion efficiency for a single junction photovoltaic device.

Various methods for forming CIGS materials are known, and the present scope is not limited to those specific methods disclosed herein. In general, the deposition of CIGS materials can result in the formation of a bilayer structure, where CIS forms at or near the surface of the material and Ga appears deeper in the structure forming a bilayer structure of surface CIS on top of a CIGS layer. Because the first 1 micron of depth in the CIGS layer is the absorption region for blue wavelengths of light, this bilayer structure can be inherently inefficient due to the fact that Ga helps to widen the bandgap but is often located within the lattice deeper than 1 micron from the CIGS surface. Thus the deeper segregation of Ga in the CIGS lattice can adversely affect the open circuit voltage of the device. Accordingly, it can be useful to stabilize the CIGS layer to reduce bilayer formation. In one aspect, for example, the films can be annealed at temperatures greater than about 370° C. to reduce such bilayer formation.

Additionally, doping the CIGS material with a dopant can increase the efficiency of a CIGS device. In one aspect, for example, adding sulfur to CIGS semiconductor materials during deposition can result in a conversion efficiency improvement of about 2%. Ultra short pulse duration lasers can be used, for example, to locally incorporate various elemental species into the CIGS material, such as, for example, into the top surface of the CIGS material. In one aspect, laser incorporation of a CIGS material with sulfur as a substitutional replacement for selenium can widen the bandgap and create conditions for higher efficiencies on single junction photovoltaics. Specifically, sulfur incorporation via short pulse lasers can result in a thin alloyed layer on the surface of the substrate. In one non-limiting example, such a thin layer can be from about 0.3 μm to about 1 μm thick. By applying this technique to CIGS materials, device efficiencies can be improved and manufacturing costs can be reduced. The segregation of gallium into the bulk of the CIGS layer and away from the surface results in a lower bandgap layer at the surface. The incorporation of an element such as sulfur by laser doping can correct the lower bandgap layer at the surface because sulfur shifts the bandgap to higher energies. It should be understood that other element introduction or alloying techniques can be employed to incorporate an element into the device. One example of such a technique is ion implantation.

Additionally, in some aspects a textured region can be formed on the CIGS material. While any technique of texturing is contemplated, in one aspect short pulse laser processing can be used. Such laser texturing can be performed simultaneously with laser incorporation of the element to form the textured region, or the laser texturing can be performed as a process that is separate from laser incorporation. The textured region can enhance light capture/trapping and improve the collection efficiency of the photovoltaic device. When the laser texturing and laser incorporation processes are combined, a reduction in manufacturing costs can be achieved by eliminating a separate step of surface texturing from the process flow while at the same time optimizing the material composition for maximum cell efficiency.

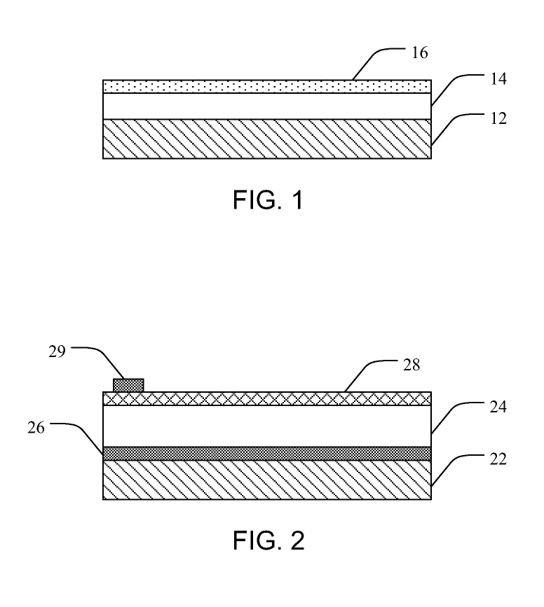

FIG. 1 shows a CIGS device including a support substrate 12 and a CIGS layer 14 disposed on the support substrate. An upper region 16 of the CIGS layer includes an element that is a substitutional replacement for Se. The substitutional replacement can be a total replacement of Se or only a partial replacement of Se. In some aspects, the upper region can include a textured region formed either concomitantly with the incorporation of the element into the upper region or as a separate process. Such a CIGS design can achieve higher conversion efficiencies than have been demonstrated in previous devices. In one aspect, for example, the CIGS device can achieve a conversion efficiency of greater than or equal to about 15%. In another aspect, the CIGS device can achieve a conversion efficiency of greater than or equal to about 20%. In yet another aspect, the CIGS device can achieve a conversion efficiency of greater than or equal to about 25%. It should be noted that the values described as conversion efficiencies refer to measurements of a single or multi-junction device measured under on sun (i.e. not concentrated). Additionally, incorporating or alloying an upper region of the CIGS layer with an element such as sulfur can act to passivate the upper surface of the layer.

It should also be noted that, in addition to the element being present in an upper region of the CIGS layer, in some aspects the element can be present at deeper levels within the layer. In one aspect, for example, the element can be present throughout all or substantially all of the CIGS layer. The element can be uniformly dispersed throughout the CIGS layer, or it can be dispersed throughout the CIGS layer but concentrated more highly in one region of the CIGS layer compared to another region. As one example, the element can be more highly concentrated at the upper region of the CIGS layer.

The devices according to aspects of the present disclosure can be used in a variety of optoelectronic applications. Non-limiting examples include solar cells, imagers, and the like. As such, any type of device that can utilize these semiconductor materials are considered to be within the present scope.

Various support substrate materials are contemplated for use in the present devices, and any support substrate material capable of receiving the CIGS layer and supporting the device are considered to be within the present scope. Non-limiting examples include glass, polymeric materials, metals, metal foils, ceramics, semiconductors, and the like, including combinations thereof. Additionally, the substrate can be rigid or flexible.

A variety of semiconductor materials are contemplated for use with the devices and methods according to aspects of the present disclosure. While much of the present disclosure has referred to CIGS materials, the present disclosure is not limited to such. It is also contemplated that similar substitutional doping can be performed on related materials, including CIS, CI, CZT, CZTS, CdTe (cadmium telluride), and the like. As such, the present disclosure relating to CIGS should also be applied to such related materials where applicable.

The CIGS material can be of any thickness that allows the desired property or functionality of the device, and thus any such thickness of CIGS material is considered to be within the present scope. In one aspect, for example, the CIGS material can be from about 20 nm to about 5 μm thick. In another aspect, the CIGS material can be from about 500 nm to about 5 μm thick. In yet another aspect, the CIGS material can be from about 1 μm to about 3 μm thick. In a further aspect, the CIGS material can be from about 500 nm to about 5 μm thick. In yet another aspect, the CIGS material can be from about 5 μm to about 50 μm thick.

A variety of elemental materials can be used, and any such material capable of shifting the bandgap of a semiconductor material in a manner according to aspects of the present disclosure are considered to be within the present scope. It should be noted that the particular element utilized can vary depending on the material being modified, as well as the intended use of the resulting material. In one aspect, for example, the element can be from the chalcogen family, such as, for example, S, Se, and Te. In one specific aspect, the element can be S. In one aspect, S can be present at an atomic concentration of from about 0.1 to about 20 at %. It should be noted that the scope of elemental materials incorporated into the semiconductor material should include, not only the element materials themselves, but also materials in forms that deliver such elements. For example, S materials includes not only S but also any material capable being used to introduce S into the target region, such as, for example, H₂S, SF₆, SO₂, and the like, including combinations thereof. It is understood that other element containing compounds can be used depending on the desired semiconductor properties.

It is also contemplated that the absorption layer can be doped with a dopant. Such dopants can be incorporated into the semiconductor material by any process known, including, without limitation, laser doping, ion implantation, diffusion doping, and the like. A dopant can be either a charge donating or a charge accepting dopant species. More specifically, an electron donating or a hole donating species can cause a region to become more positive or negative in polarity as compared to the substrate upon which the rests. In one aspect, for example, the doped region can be p-doped. In another aspect, the doped region can be n-doped. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. In one specific aspect, the dopant can be S. It is understood that other dopant containing compounds can be used depending on the desired semiconductor properties. These include non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, POCl₃, P₂O₅, and the like, including combinations thereof. Non-limiting examples of chlorine-containing compounds can include Cl₂, SiH₂Cl₂, HCl, to SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆. As one non-limiting example, SF₆ gas is a good carrier for the incorporation of sulfur into a substrate via a laser process without significant adverse effects on the material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the substrate.

When present, the textured region can function to diffuse electromagnetic radiation, to redirect electromagnetic radiation, and/or to absorb electromagnetic radiation, thus increasing the conversion efficiency of the device. The textured region can include surface features to further increase the effective absorption length of the device. Non-limiting examples of shapes and configurations of surface features include cones, pillars, pyramids, micolenses, quantum dots, inverted features, gratings, protrusions, sphere-like structures, and the like, including combinations thereof. Additionally, surface features can be micron-sized, nano-sized, or a combination thereof. For example, cones, pyramids, protrusions, and the like can have an average height within this range. In one aspect, the average height would be from the base of the feature to the distal tip of the feature. In another aspect, the average height would be from the surface plane upon which the feature was created to the distal tips of the feature. In one specific aspect, a feature (e.g. a cone) can have a peak to valley height of from about 50 nm to about 2 μm. In another specific aspect, a feature can have a peak to valley height of from about 10 nm to about 0.5 μm. In yet another specific aspect, a feature can have a peak to valley height of from about 0.1 nm to about 0.5 μm. As another example, quantum dots, microlenses, and the like can have an average diameter within the micron-sized and/or nano-sized range.

The textured region can be formed by various techniques, including plasma etching, reactive ion etching, porous silicon etching, lasing, chemical etching (e.g. anisotropic etching, isotropic etching), nanoimprinting, material deposition, selective epitaxial growth, and the like. In one aspect, the support substrate can be textured prior to depositing the CIGS layer. Certain CIGS deposition techniques such as PVD can form a conformal CIGS layer over the textured surface, thus forming a textured region from the textured support substrate.

One effective method of producing a textured region is through laser processing. Such laser processing allows discrete target areas of a substrate to be textured, as well as entire surfaces. A variety of techniques of laser processing to form a textured region are contemplated, and any technique capable of forming such a region should be considered to be within the present scope. Laser treatment or processing can allow, among other things, enhanced absorption properties and thus increased electromagnetic radiation focusing and detection.

In one aspect, for example, a target region of the substrate to be textured can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a substrate material is irradiated with laser radiation to form a textured or surface modified region. Such laser processing can occur with or without the incorporation of an element or a dopant material. In those aspects whereby such materials are used, the laser can passed through an element or dopant carrier and onto the substrate surface. In this way, the element or dopant from the carrier is introduced into the target region of the substrate material. Such a region incorporated into a substrate material can have various benefits in accordance with aspects of the present disclosure. For example, the textured region typically has a textured surface that increases the surface area and increases the probability of radiation absorption. In one aspect, such a textured region is a substantially textured surface including micron-sized and/or nano-sized surface features that have been generated by the laser texturing. In another aspect, irradiating the surface of a substrate material includes exposing the laser radiation to an element such that irradiation incorporates the element into the substrate.

The type of laser radiation used to surface modify a material can vary depending on the material and the intended modification. Any laser radiation known in the art can be used with the devices and methods of the present disclosure. There are a number of laser characteristics, however, that can affect the surface modification process and/or the resulting product including, but not limited to, the wavelength of the laser radiation, pulse width, pulse fluence, pulse frequency, polarization, laser propagation direction relative to the semiconductor material, etc. In one aspect, a laser can be configured to provide pulsatile lasing of a material. A short-pulsed laser is one capable of producing femtosecond, picosecond, and/or nanosecond pulse durations. Laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 900 picoseconds. In another aspect, laser pulse widths can be in the range of from about 900 picoseconds to 100 nanoseconds. In another aspect, laser pulse widths are in the range of from about 50 to 500 femtoseconds.

The number of laser pulses irradiating a target region can be in a range of from about 1 to about 2000. In one aspect, the number of laser pulses irradiating a target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

FIG. 2 shows an exemplary aspect of a photovoltaic device. In such an aspect, the photovoltaic device can include a support substrate 22 and a CIGS layer 24 coupled to the support substrate. A first electrical contact 26 can be included between the support substrate and the CIGS layer. A textured region 28 is coupled to the CIGS layer opposite to the support substrate. The textured region can be formed as the CIGS layer is alloyed with the element or as a separate process. In one aspect, the textured region can be located on the opposite side of the CIGS layer near the first electrical contact (not shown). A second electrical contact can be electrically coupled to the CIGS layer opposite the first electrical contact. Additionally, in some aspects the second electrical contact can be a transparent conductive oxide material used as a conductive layer on top of the photovoltaic device (not shown). Non-limiting examples include zinc oxide (ZnO), indium tin oxide (ITO), and the like.

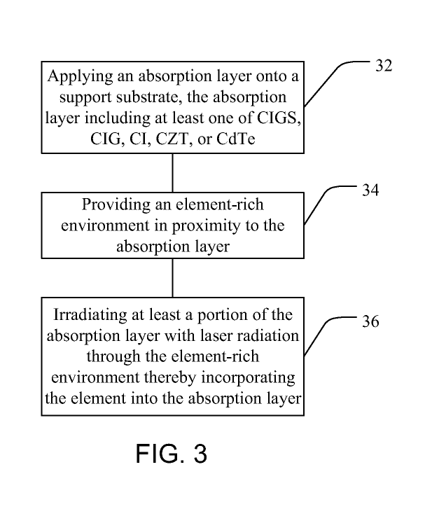

In another aspect of the present disclosure, a method of making a photovoltaic device having enhanced conversion efficiency is provided. In one aspect, as is shown in FIG. 3, such a method can include applying an absorption layer onto a support substrate, wherein the absorption layer includes at least one of CIGS, CIG, CI, CZT, CdTe, and combinations thereof 32, providing an element-rich environment in proximity to the absorption layer 34, and irradiating at least a portion of the absorption layer with laser radiation through the element-rich environment thereby incorporating the element into the absorption layer 36. In one specific aspect, the absorption layer is CIGS. It should be understood that the term “in proximity” refers to a placement of the element-rich environment in a location sufficiently close to the absorption layer to allow the element to be incorporated therein by laser irradiation. In some aspects the element-rich environment is in contact with or substantially in contact with the absorption layer. In other aspects the element-rich environment is positioned between a laser system and the absorption layer, while being sufficiently close to the absorption layer to allow laser incorporation of the element. Furthermore, in another aspect the method can include annealing the irradiated substrate at a temperature in the range of from about 200° C. to about 600° C. (not shown).

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of making an optoelectronic device, comprising:
applying an absorption layer onto a support substrate, the absorption layer including a material selected from the group consisting of CIGS, CIG, CI, CZT, CdTe, and combinations thereof;
providing an element-rich environment in proximity to the absorption layer; and
irradiating at least a portion of the absorption layer with laser radiation through the element-rich environment thereby incorporating the element into the absorption layer.

2. The method of claim 1, further comprising annealing the absorption layer to a temperature of from about 200° C. to about 600° C.

3. The method of claim 1, wherein the element includes a member selected from the group consisting of S, Se, Te, and combinations thereof.

4. The method of claim 1, wherein the element is S.

5. The method of claim 1, further comprising forming a textured region at the absorption layer.

6. The method of claim 5, wherein the textured region is formed by a short pulse laser.

7. The method of claim 6, wherein the formation of the textured region and the incorporation of the element into the absorption layer are performed substantially simultaneously with the short pulse laser.

8. The method of claim 7, wherein the formation of the textured region and the incorporation of the element into the absorption layer are performed with the short pulse laser having a pulse duration of from about 1 femtosecond to about 900 picoseconds.

9. The optoelectronic device of claim 1.

10. The device of claim 9, wherein the conversion efficiency of the device is at least about 15%.

11. The device of claim 9, wherein the conversion efficiency of the device is at least about 20%.

12. The device of claim 9, wherein the conversion efficiency of the device is at least about 25%.
